(19) United States
(12) Patent Application Publication
(10) Pub. No.: US 2015/0069593 A1
(43) Pub. Date: Mar. 12, 2015

(54) SEMICONDUCTOR DEVICE AND METHOD OF MANUFACTURING SAME

(71) Applicant: KABUSHIKI KAISHA TOSHIBA, Tokyo (JP)

(72) Inventors: Shinichi Koyama, Himeji-Shi (JP); Koji Araki, Himeji-Shi (JP); Tatsuo Tonedachi, Himeji-Shi (JP); Kazumi Otani, Himeji-Shi (JP)

(73) Assignee: KABUSHIKI KAISHA TOSHIBA, Tokyo (JP)

(21) Appl. No.: 14/202,942

(22) Filed: Mar. 10, 2014

(30) Foreign Application Priority Data
Sep. 12, 2013 (JP) 2013-189548

(51) Int. Cl. H01L 23/495; H01L 21/50

(52) U.S. Cl. CPC H01L 23/495; H01L 21/50
USPC 257/676; 438/123

(57) ABSTRACT

In one embodiment, a semiconductor device includes a lead frame including a chip mounting portion and a lead portion separated from the chip mounting portion and having the same thickness as the chip mounting portion, a level of an upper face of the chip mounting portion being same as a level of an upper face of the lead portion. The device further includes a semiconductor chip mounted on the upper face of the chip mounting portion and electrically connected to the lead portion. The device further includes a molding resin which collectively seals up the lead frame and the semiconductor chip. The device further includes a metal film covering parts of rear faces of the chip mounting portion and the lead portion.

### CROSS REFERENCE TO RELATED APPLICATION

This application is based upon and claims the benefit of priority from the prior Japanese Patent Application No. 2013-189548, filed on Sep. 12, 2013, the entire contents of which are incorporated herein by reference.

### FIELD

Embodiments described herein relate to a semiconductor device and a method of manufacturing the same.

### BACKGROUND

In a pressed lead frame including a chip mounting portion and a lead portion, the chip mounting portion to be mounted with a semiconductor chip is shifted upward from the lead portion in order to provide a space to be filled with a molding resin on the rear face side of the semiconductor chip. Such a structure is formed by bending (pressing) a metal plate to serve as the lead frame. The pressed lead frame therefore has to include a region used to bend the lead frame, in addition to regions corresponding to the chip mounting portion and the lead portion. Accordingly, the size of the semiconductor chip that can be mounted is limited in the pressed lead frame. It is therefore difficult to improve the chip mounting capability of the lead frame. In addition, the lead frame has to be made larger in order to mount a large-size semiconductor chip. This requirement leads to an increase in material costs.

An etched lead frame has been proposed as an alternative to the pressed lead frame. The etched lead frame is formed by etching a metal plate. In the etched lead frame, the thickness of a chip mounting portion is smaller than the thickness of a lead portion. Therefore, a space to be filled with a molding resin is present on the rear face side of a semiconductor chip. Accordingly, the etched lead frame need not have a region used to bend the lead frame. Consequently, the etched lead frame is not restricted in size of the semiconductor chip that can be mounted, and therefore has a high chip mounting capability.

However, since the etched lead frame requires an etching process, the etched lead frame is expensive compared with the pressed lead frame. In addition, it is difficult to uniformly heat the etched lead frame in a case where heat is applied to the etched lead frame in order to mount the semiconductor chip, since the thickness of the etched lead frame is not uniform. Accordingly, a temperature difference arises in the etched lead frame, and therefore warpage may be generated in the etched lead frame. The semiconductor chip mounted on the chip mounting portion may be broken due to this warpage, causing a failure in a semiconductor device.

### BRIEF DESCRIPTION OF THE DRAWINGS

FIGS. 1A and 1B are drawings of a semiconductor device of a first embodiment;

FIGS. 2A and 2B are drawings of a lead frame of the first embodiment;

FIG. 3 is a flowchart showing a method of manufacturing the semiconductor device of the first embodiment;

FIG. 4 is a drawing illustrating a cross section of a semiconductor device of a modified example of the first embodiment; and

FIGS. 5A and 5B are drawings of semiconductor devices of a second embodiment and its modified example.

### DETAILED DESCRIPTION

Embodiments will now be explained with reference to the accompanying drawings. The present invention is not limited to these embodiments. Common components are denoted by common reference numerals throughout the drawings and will not be discussed again. The drawings are schematic views used to facilitate the description and understanding of the invention, and may therefore differ in shape, dimension, ratio and the like in some places from actual devices. Design changes can be made to these devices as appropriate by taking into consideration the following description and known technology. In the following embodiments, a vertical direction of a semiconductor device, a semiconductor chip and the like indicates a relative direction when a surface of the semiconductor chip where semiconductor elements are arranged is faced up, and may therefore differ from a vertical direction based on gravitational acceleration in some cases. Also, expressions such as “same”, “uniform” and “planar” used for thicknesses, shapes and the like not only mean that they are mathematically (geometrically) identical, but also signify that they include those degrees of difference, roughness and the like which are industrially acceptable in a process of manufacturing semiconductor devices.

In one embodiment, a semiconductor device includes a lead frame including a chip mounting portion and a lead portion separated from the chip mounting portion and having the same thickness as the chip mounting portion, a level of an upper face of the chip mounting portion being same as a level of an upper face of the lead portion. The device further includes a semiconductor chip mounted on the upper face of the chip mounting portion and electrically connected to the lead portion. The device further includes a molding resin which collectively seals up the lead frame and the semiconductor chip. The device further includes a metal film covering parts of rear faces of the chip mounting portion and the lead portion.

### First Embodiment

### (1) Semiconductor Device

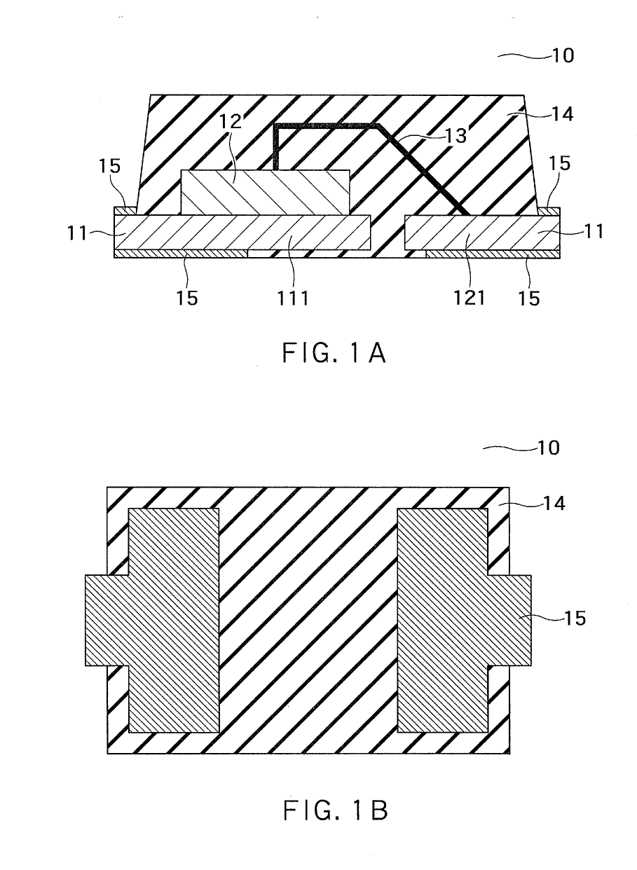

FIGS. 1A and 1B are drawings of a semiconductor device 10 of a first embodiment.

FIG. 1A illustrates a cross section of the semiconductor device 10, and FIG. 1B illustrates a rear face of the semiconductor device 10. The semiconductor device 10 of the first embodiment will be described with reference to FIGS. 1A and 1B.

The semiconductor device 10 of the first embodiment includes a lead frame 11, a semiconductor chip 12, a wire 13, and a molding resin 14. The lead frame 11 includes a chip mounting portion 111 and a lead portion 121 separated from the chip mounting portion 111. The semiconductor chip 12 is mounted on an upper face of the chip mounting portion 111. An electrode arranged on an upper face of the semiconductor chip 12 is electrically connected to an upper face of the lead portion 121 via the wire 13. In addition, the molding resin 14 collectively seals up the lead frame 11, the semiconductor chip 12, and the wire 13.

The respective leading ends of the chip mounting portion 111 and the lead portion 121 protrude from the molding resin 14. A metal film 15 is formed on these protruding portions. In addition, as illustrated in FIG. 1B, parts of rear faces of the chip mounting portion 111 and the lead portion 121 are exposed out of the molding resin 14 also on the rear face of the semiconductor device 10. A metal film 15 is also formed on these exposed portions.

### (2) Lead Frame

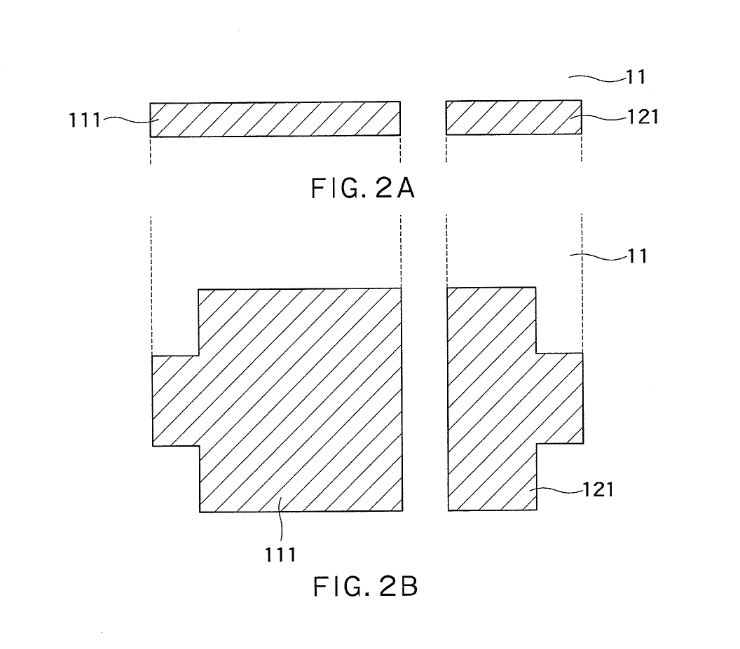

FIGS. 2A and 2B are drawings of the lead frame 11 of the first embodiment.

FIG. 2A illustrates a cross section of the lead frame 11, and FIG. 2B illustrates the upper face of the lead frame 11. The lead frame 11 of the first embodiment will be described with reference to FIGS. 2A and 2B. Note however that a lead frame actually used in a manufacturing process is a continuous chain of the lead frames 11 illustrated in FIGS. 2A and 2B.

As described earlier, the lead frame 11 includes the chip mounting portion 111 and the lead portion 121 separated from the chip mounting portion 111. In addition, as illustrated in FIG. 2A, the chip mounting portion 111 and the lead portion 121 have the same thickness, and no steps are present between the chip mounting portion 111 and the lead portion 121. In other words, the lead frame 11 has a uniform thickness, and a level of the upper face of the chip mounting portion 111 is same as a level of the upper face of the lead portion 121. Accordingly, the lead frame 11 can be inexpensively manufactured without the need for an etching process and a bending process (pressing process).

### (3) Method of Manufacturing Semiconductor Device

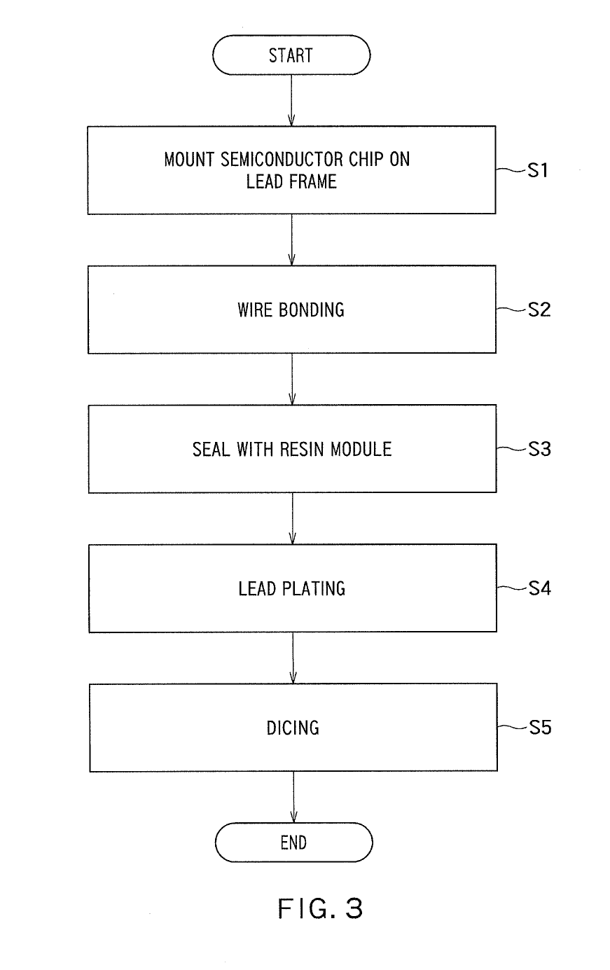

FIG. 3 is a flowchart showing a method of manufacturing the semiconductor device 10 of the first embodiment. The method of manufacturing the semiconductor device 10 will be described with reference to FIG. 3.

In step S1, the semiconductor chip 12 is mounted on the upper face of the chip mounting portion 111 of the lead frame 11. At this time, heat is applied to the lead frame 11. Since the heat can be uniformly applied to the lead frame 11 having a uniform thickness, a temperature difference is less likely to arise in the lead frame 11. Accordingly, it is possible to avoid the warpage of the lead frame 11 due to the temperature difference and the breakage of the semiconductor chip 12 due to the warpage.

In step S2, the wire 13 for electrically connecting the electrode and the lead portion 121 is bonded to the electrode arranged on the upper face of the semiconductor chip 12 and to the upper face of the lead portion 121.

In step S3, the lead frame 11, the semiconductor chip 12, and the wire 13 are collectively sealed up with the molding resin 14. A sealing process is carried out by injecting the molding resin 14 into a metal mold including the lead frame 11. At this time, the sealing is performed by using the metal mold so as to expose the parts of the rear faces of the chip mounting portion 111 and the lead portion 121 out of the molding resin 14. It is possible, by sealing up the semiconductor device by using the metal mold, to cover the rear face of the semiconductor chip 12 with the molding resin 14, while exposing the parts of the rear faces of the chip mounting portion 111 and the lead portion 121 of the lead frame 11 out of the molding resin 14, even when the lead frame 11 which is neither bent (pressed) nor etched and has a uniform thickness is used.

In step 4, the metal film 15 is formed on the parts of the chip mounting portion 111 and the lead portion 121 exposed out of the molding resin.

In step 5, a plurality of semiconductor devices 10 coupled by the lead frame 11 is uncoupled (divided into individual pieces).

In the lead frame 11 of the first embodiment, the chip mounting portion 111 and the lead portion 121 have the same thickness, no steps are present between the chip mounting portion 111 and the lead portion 121, and the level of the upper face of the chip mounting portion 111 is same as the level of the upper face of the lead portion 121. In a pressed lead frame, a bent region where a semiconductor chip cannot be mounted is present between a chip mounting portion and a lead portion. However, such a region is not present in the lead frame 11 of the first embodiment. It is therefore possible to mount a large-size semiconductor chip by the use of the lead frame 11, and thereby improve the chip mounting capability of the semiconductor device. In addition, the lead frame 11 can be manufactured inexpensively without the need for etching and bending processes. Even in a case where such a lead frame 11 is used to perform the sealing, the rear face of the semiconductor chip 12 can be covered with the molding resin 14 while exposing the parts of the rear faces of the chip mounting portion 111 and the lead portion 121 out of the molding resin 14, by performing the sealing using the metal mold.

According to the first embodiment, the lead frame 11 has a uniform thickness. Therefore, heat is uniformly applied to the lead frame 11 when the lead frame 11 is heated, and a temperature difference is less likely to arise in the lead frame 11. Consequently, it is possible to avoid the warpage of the lead frame 11 due to the temperature difference. The semiconductor chip 12 therefore does not become broken due to the warpage. That is, it is possible to avoid the failure of the semiconductor device 10 due to the breakage of the semiconductor chip 12.

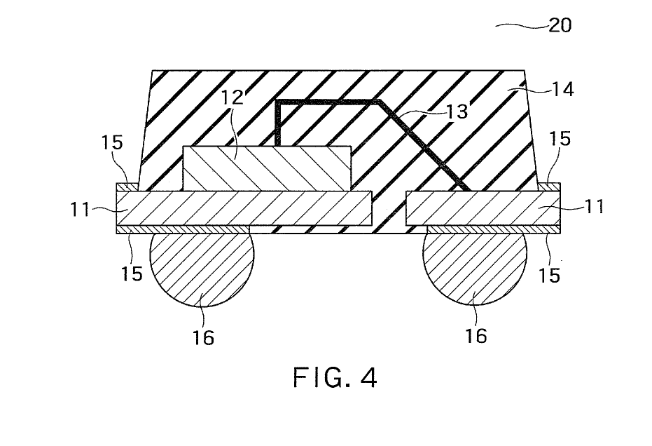

FIG. 4 is a drawing illustrating a cross section of a semiconductor device 20 of a modified example of the first embodiment.

The semiconductor device 20 includes solder balls 16 which are formed on the rear face side of the semiconductor device 20 and are in contact with the metal film 15. The semiconductor device 20 differs from the semiconductor device 10 of the first embodiment in this regard. When the semiconductor device 20 is mounted on an application substrate, the semiconductor device 20 is electrically connected to the application substrate via the solder balls 16. At this time, since the electrical connection can be made by the solder balls 16 located immediately under the semiconductor device 20, it is possible to reduce the area of a region (foot pattern) on the application substrate to be mounted with the semiconductor device 20, compared with a case in which the electrical connection is made by terminals located on a lateral side of the semiconductor device.

### Second Embodiment

### (1) Semiconductor Device

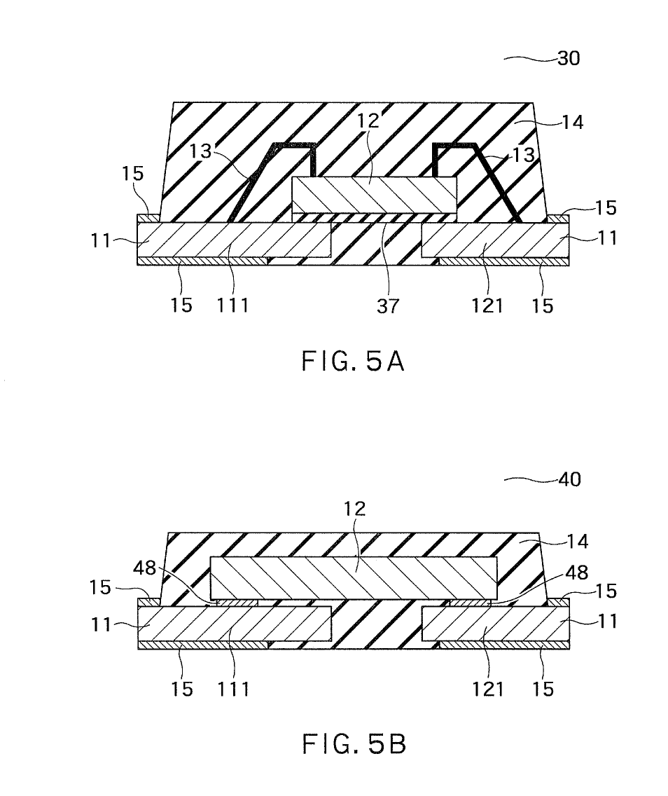

FIGS. 5A and 5B are drawings of semiconductor devices 30 and 40 of a second embodiment and its modified example.

The method of mounting the semiconductor chip 12 of the second embodiment differs from that of the first embodiment. FIG. 5A illustrates a cross section of the semiconductor device 30 of the second embodiment. The second embodiment will be described using FIG. 5A.

Similarly to the first embodiment, the semiconductor device 30 of the second embodiment includes the semiconductor chip 12, the wire 13 and the molding resin 14. In addition, the semiconductor device 30 includes the lead frame 11 having the same structure as that of the lead frame 11 in the first embodiment. Unlike the first embodiment, however, the semiconductor chip 12 is mounted so as to extend over the upper faces of the chip mounting portion 111 and the lead portion 121. That is, the semiconductor chip 12 is mounted on both the chip mounting portion 111 and the lead portion 121. The semiconductor chip 12 is mounted on the chip mounting portion 111 and the lead portion 121 via an insulating adhesive material 37. The insulating adhesive material 37 is, for example, an insulating die attach film (DAF), an adhesive agent, or paste.

According to the second embodiment, the chip mounting portion 111 and the lead portion 121 of the lead frame 11 have the same thickness as similar to the first embodiment. In addition, no steps are present between the chip mounting portion 111 and the lead portion 121, and therefore the level of the upper face of the chip mounting portion 111 is same as the level of the upper face of the lead portion 121. Accordingly, it is easy to mount the semiconductor chip 12 so as to extend over the upper faces of the chip mounting portion 111 and the lead portion 121. As a result, it is possible to mount the semiconductor chip 12 wider in area than the chip mounting portion 111 without having to make the lead frame 11 larger. That is, it is possible to further improve the chip mounting capability of the semiconductor device.

In addition, since the second embodiment uses the same lead frame 11 as that of the first embodiment, it is possible to obtain the same advantageous effects as those of the first embodiment.

The semiconductor device 30 of the second embodiment can be formed by mounting the semiconductor chip 12 so as to extend over the upper faces of the chip mounting portion 111 and the lead portion 121 in the manufacturing method of the first embodiment.

FIG. 5B illustrates a cross section of the semiconductor device 40 of the modified example of the second embodiment. In this semiconductor device 40 of the modified example, the semiconductor chip 12 is connected to the chip mounting portion 111 and the lead portion 121 via metal bumps 48. In this modified example, electrodes (for example, through silicon via (TSV) electrodes) are arranged on the rear face of the semiconductor chip 12, and these electrodes are electrically connected to the chip mounting portion 111 and the lead portion 121 via the metal bumps 48. As a result, it is possible to keep the thickness of the semiconductor device 40 smaller, compared with the electrical connection using the wire 13.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

1. A semiconductor device comprising:
a lead frame including a chip mounting portion and a lead portion separated from the chip mounting portion and having the same thickness as the chip mounting portion, a level of an upper face of the chip mounting portion being same as a level of an upper face of the lead portion;
a semiconductor chip mounted on the upper face of the chip mounting portion and electrically connected to the lead portion;
a molding resin which collectively seals up the lead frame and the semiconductor chip; and
a metal film covering parts of rear faces of the chip mounting portion and the lead portion.

2. The device of claim 1, wherein the semiconductor chip is electrically connected to the lead portion via a wire.

3. The device of claim 2, wherein the molding resin collectively seals up the lead frame, the semiconductor chip and the wire.

4. The device of claim 1, wherein the metal film covers the parts of the rear faces of the chip mounting portion and the lead portion, and parts of front faces of the chip mounting portion and the lead portion.

5. The device of claim 1, wherein the semiconductor chip is mounted so as to extend over the upper faces of the chip mounting portion and the lead portion.

6. The device of claim 5, wherein the semiconductor chip is mounted on the upper faces of the chip mounting portion and the lead portion via an insulator.

7. The device of claim 6, wherein the insulator is an insulating adhesive material.

8. The device of claim 5, wherein the semiconductor chip is mounted on the upper faces of the chip mounting portion and the lead portion via a conductor.

9. The device of claim 8, wherein the conductor is a metal bump.

10. The device of claim 1, further comprising a solder ball in contact with the metal film.

11. A method of manufacturing a semiconductor device, comprising:
preparing a lead frame including a chip mounting portion and a lead portion separated from the chip mounting portion and having the same thickness as the chip mounting portion, a level of upper face of the chip mounting portion being same as a level of an upper face of the lead portion;
mounting a semiconductor chip on the upper face of the chip mounting portion;
electrically connecting the semiconductor chip to the lead portion;
collectively sealing up the lead frame and the semiconductor chip with a molding resin so as to expose parts of rear faces of the chip mounting portion and the lead portion out of the molding resin; and
forming a metal film on the parts of the rear faces of the chip mounting portion and the lead portion exposed out of the molding resin.

12. The method of claim 11, wherein heat is applied to the lead frame when the semiconductor chip is mounted on the upper face of the chip mounting portion.

13. The method of claim 11, wherein the semiconductor chip is electrically connected to the lead portion via a wire.

14. The method of claim 13, wherein the lead frame, the semiconductor chip and the wire are collectively sealed up with the molding resin.

15. The method of claim 11, wherein the sealing is performed by injecting the molding resin into a metal mold including the lead frame.

16. The method of claim 11, wherein the metal film is formed on the parts of the rear faces of the chip mounting portion and the lead portion exposed out of the molding resin, and on parts of front faces of the chip mounting portion and the lead portion exposed out of the molding resin.

17. The method of claim 11, wherein the semiconductor chip is mounted so as to extend over the upper faces of the chip mounting portion and the lead portion.

18. The method of claim 17, wherein the semiconductor chip is mounted on the upper faces of the chip mounting portion and the lead portion via an insulator.

19. The method of claim 17, wherein the semiconductor chip is mounted on the upper faces of the chip mounting portion and the lead portion via a conductor.

20. The method of claim 11, further comprising forming a solder ball in contact with the metal film.
